(19) United States
(12) Patent Application Publication
(10) Pub. No.: US 2025/0273442 A1
(43) Pub. Date: Aug. 28, 2025

(54) PLASMA PROCESSING DEVICE

(71) Applicant: SAMSUNG ELECTRONICS CO., LTD., Suwon-si (KR)

(72) Inventors: Gyoseon Choo, Suwon-si (KR); Juneeok Leem, Suwon-si (KR); Minyoung Hur, Suwon-si (KR); Kyungsun Kim, Suwon-si (KR); Donghyeon Na, Suwon-si (KR); Sangrok Oh, Suwon-si (KR); Yongwoo Lee, Suwon-si (KR)

(21) Appl. No.: 18/815,363

(22) Filed: Aug. 26, 2024

(30) Foreign Application Priority Data
Feb. 27, 2024 (KR) 10-2024-0028189

(51) Int. Cl. H01J 37/32

(52) U.S. Cl. CPC H01J 37/32669; H01J 37/32165; H01J 37/32715; H01J 37/32972; H01J 2237/2007; H01J 2237/334

(57) ABSTRACT

A plasma processing device includes an electrostatic chuck supporting a substrate in a chamber space; an upper electrode located in an upper portion of a chamber body; a magnetic field control device including at least one coil located above the upper electrode and forming a magnetic field in the chamber space; and a control unit controlling at least one current flowing through the at least one coil such that a magnetic flux density at a target position on a boundary of the sheath region has a value in which an electronic rotation period at the target position due to the magnetic field matches an electronic oscillation period determined by at least one of a first high-frequency power source and a second high-frequency power source.

### CROSS-REFERENCE TO RELATED APPLICATION

This application claims the benefit of priority to Korean Patent Application No. 10-2024-0028189, filed on Feb. 27, 2024, in the Korean Intellectual Property Office, the entirety of which is incorporated herein by reference.

### BACKGROUND

Semiconductor devices may be manufactured using a plasma processing device. For example, a plasma processing device may include a plasma film deposition device or a plasma etching device. In order to ensure uniform quality of manufactured semiconductor devices, it is important for the plasma processing device to uniformly control distribution of plasma in a chamber space.

### SUMMARY

Some aspects of the present disclosure provide plasma processing devices capable of increasing plasma density in a region corresponding to a central portion of a substrate in a chamber space, using a magnetic field control device.

Some aspects of the present disclosure provide plasma processing devices capable of widely controlling process distribution over a wide range and uniformly controlling process distribution, using a magnetic field control device.

According to some aspects of the present disclosure, a plasma processing device includes: a chamber body defining a chamber space; an electrostatic chuck arranged to support a substrate in the chamber space; an upper electrode located at an upper portion of the chamber body; a multiple high-frequency power supply including: a first power supply configured to apply a first high-frequency power to the upper electrode, and a second power supply configured to apply a second high-frequency power to the electrostatic chuck, wherein at least one of the first high-frequency power or the second high-frequency power excites a process gas supplied to the chamber space to form a bulk plasma region and a sheath region in the chamber space, and wherein the multiple high-frequency power supply is configured to apply the at least one of the first high-frequency power or the second high-frequency power singly or simultaneously; a magnetic field control device including at least one coil located above the upper electrode, wherein the magnetic field control device is configured to form a magnetic field in the chamber space using at least one current flowing through the at least one coil; and a control unit configured to control the at least one current flowing through the at least one coil such that a magnetic flux density at a target position on a boundary of the sheath region has a value that results in (i) an electronic rotation period at the target position due to the magnetic field matching (ii) an electronic oscillation period that depends on the at least one of the first high-frequency power and the second high-frequency power.

According to some aspects of the present disclosure, a plasma processing device includes: a chamber body defining a chamber space; an electrostatic chuck arranged to support a substrate in the chamber space; an upper electrode located at an upper portion of the chamber body; a multiple high-frequency power supply including: a first power supply configured to apply a first high-frequency power to the upper electrode, and a second power supply configured to apply a second high-frequency power to the electrostatic chuck, wherein at least one of the first high-frequency power or the second high-frequency power excites a process gas supplied to the chamber space to form a bulk plasma region and a sheath region in the chamber space, and wherein the multiple high-frequency power supply is configured to apply the at least one of the first high-frequency power or the second high-frequency power singly or simultaneously; an optical interface configured to receive light from the chamber space; a spectrometer configured to monitor a light intensity at a target wavelength of the light; a magnetic field control device including at least one coil located above the upper electrode, wherein the magnetic field control device is configured to form a magnetic field in the chamber space using at least one current flowing through the at least one coil; and a control unit configured to: set at least one initial value of the at least one current, cause a plasma process to be performed on the substrate, and based on a measured value of the light intensity at the target wavelength being different from a reference value, adjust the at least one current such that a difference between the measured value and the reference value decreases.

According to some aspects of the present disclosure, a plasma processing device includes: a chamber body defining a chamber space; an electrostatic chuck arranged to support a substrate in the chamber space; an upper electrode located at an upper portion of the chamber body; a multiple high-frequency power supply including: a first power supply configured to apply a first high-frequency power to the upper electrode, and a second power supply configured to apply a second high-frequency power to the electrostatic chuck, wherein at least one of the first high-frequency power or the second high-frequency power excites a process gas supplied to the chamber space to form a bulk plasma region and a sheath region in the chamber space, and wherein the multiple high-frequency power supply is configured to apply the at least one of the first high-frequency power or the second high-frequency power singly or simultaneously; a magnetic field control device including at least one coil located above the upper electrode, wherein the magnetic field control device is configured to form a magnetic field in the chamber space using at least one current flowing through the at least one coil; and a control unit configured to: acquire a distribution map indicating a process value as a function of a distance from a center of the substrate, and based on when the process value decreasing toward the center of the substrate in the distribution map, determining at least one value of the at least one current flowing through the at least one coil such that magnetic resonance occurs at a target position at which a boundary of the sheath region and a central axis of the chamber space meet.

### BRIEF DESCRIPTION OF DRAWINGS

The above and other aspects, features, and advantages will be more clearly understood from the following detailed description, taken in conjunction with the accompanying drawings, in which:

FIG. 1 is a diagram illustrating an example of a plasma processing device.

FIG. 2 is a top view illustrating an example of a magnetic field control device.

FIG. 3 is a side view illustrating movement of electrons due to a magnetic field in an example of a plasma processing device.

FIG. 4 is a chart illustrating an example of process distribution of a plasma processing device.

FIG. 5 is a diagram illustrating an example of a method of controlling a magnetic field of a plasma processing device.

FIG. 6 is a flowchart illustrating an example of a method of controlling a magnetic field.

FIGS. 7A to 7C are charts illustrating simulation results of magnetic field distribution.

FIGS. 8A to 8C are charts illustrating etching rates as functions of position.

FIG. 9 is a diagram illustrating an example of a method of controlling a magnetic field of a plasma processing device.

FIGS. 10A and 10B are charts illustrating optical emission spectroscopy (OES) monitoring.

FIG. 11 is a flowchart illustrating an example of a method of controlling a magnetic field.

FIG. 12 is a flowchart illustrating an example of a method of correcting current values.

FIG. 13 is a chart illustrating various distribution maps associated with a method of controlling a magnetic field.

FIG. 14 is a chart illustrating an example of process distribution.

FIG. 15 is a flowchart illustrating an example of a plasma processing method.

### DETAILED DESCRIPTION

In the following description, like reference numbers refer to like elements having the same characteristics, except where noted otherwise or suggested otherwise by context.

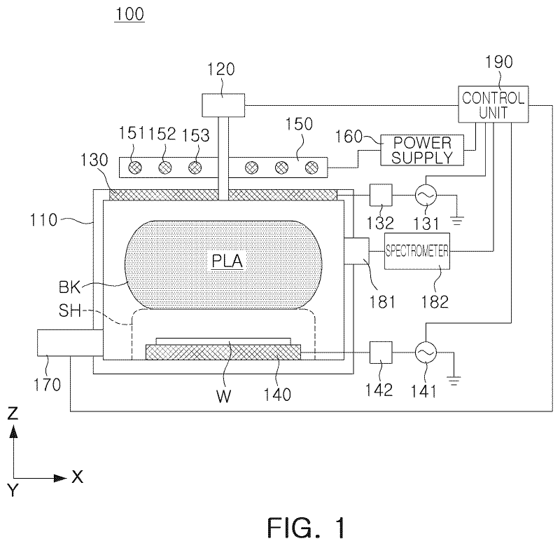

FIG. 1 is a diagram illustrating an example of a plasma processing device. Referring to FIG. 1, a plasma processing device 100 includes a chamber body 110, a gas supply device 120, an upper electrode 130, a first power supply 131, a first impedance adapter 132, an electrostatic chuck 140, a second power supply 141, a second impedance adapter 142, an electromagnet 150, a third power supply 160, an exhaust device 170, an optical interface 181, a spectrometer 182, and a control unit 190.

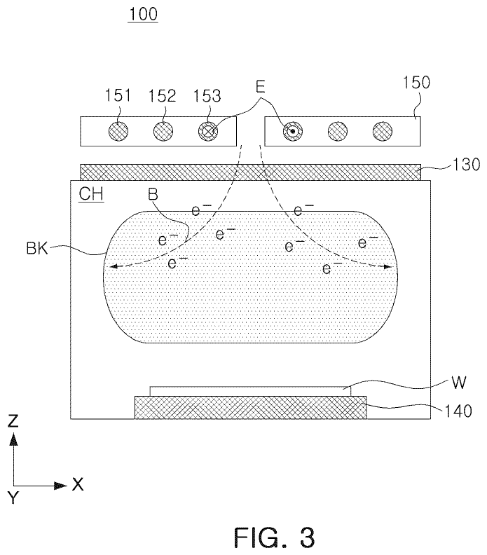

The chamber body 110 may serve as a housing forming a chamber space CH (labeled, for example, in FIG. 3) defined by an external wall. The chamber space CH may be used to perform a plasma process of processing a substrate W to be processed, using plasma PLA generated by exciting a process gas supplied by the gas supply device 120. The external wall may be formed of a material having excellent wear resistance and excellent corrosion resistance. The chamber body 110 may maintain the chamber space CH in a sealed state having a given pressure and a given temperature during the plasma process, for example, an etching process. The exhaust device 170 may be disposed on the external wall of the chamber body 110 to exhaust gas from an internal space such as the chamber space CH.

The gas supply device 120 may supply the process gas for performing the plasma process to the chamber space CH. For example, the process gas may include a gas for physical etching, such as argon (Ar) or the like, a gas for chemical etching, such as CₓF_{y} or the like, or the like.

The upper electrode 130 may be disposed in an upper portion of the chamber body 110. A first high-frequency power source, for example, an RF power source, may be applied to the upper electrode 130 by the first power supply 131.

The electrostatic chuck 140 may be disposed in the chamber space CH, and may fix the substrate W on an upper surface thereof using static electricity. A second high-frequency power source, for example, an RF power source, may be applied to the electrostatic chuck 140 by the second power supply 141. For example, the electrostatic chuck 140 may function as a lower electrode.

The process gas supplied from the gas supply device 120 may be converted into a plasma PLA state by the first high-frequency power source applied exclusively to the upper electrode 130, by the second high-frequency power source applied exclusively to the lower electrode, or by the first high-frequency power source and the second high-frequency power source that may be applied to the upper electrode 130 and the lower electrode simultaneously.

Positive ions included in the plasma PLA may be accelerated by the second high-frequency power source, and the plasma process may be performed by irradiating the accelerated ions to the substrate W. The first power supply 131 and the second power supply 141, capable of applying a power source to any one of the upper electrode 130 and the lower electrode alone or simultaneously to the upper electrode 130 and the lower electrode, may also be referred to as a multiple high-frequency power supply.

Plasma may include electrons, positive ions, and neutrons. The chamber space CH containing the plasma PLA may include a bulk plasma region BK having high-density plasma and a sheath region SH mainly containing positive ions and neutrons.

As illustrated in FIG. 1, in the plasma processing device 100, plate electrodes as the upper electrode 130 and the lower electrode may be arranged to face each other, and the plasma processing device 100 may perform the plasma process using plasma (charge coupled plasma (CCP)) generated by capacitance coupling.

In some implementations, the first impedance adapter 132 for minimizing reflected power by matching impedance of a circuit and a power source is connected between the first power supply 131 and the upper electrode 130. Likewise, the second impedance adapter 142 may be connected between the second power supply 141 and the electrostatic chuck 140.

The electromagnet 150 may be disposed on the upper electrode 130, and may form a magnetic field in the chamber space CH. The magnetic field formed in the chamber space CH may control a density of the plasma by controlling movement of the electrons included in the plasma. The electromagnet 150 may include a plurality of coils 151, 152, and 153 forming the magnetic field.

The third power supply 160 may supply a power source to the plurality of coils 151, 152, and 153 such that a current flows through each of the plurality of coils 151, 152, and 153. The third power supply 160 may form a static magnetic field in the chamber space CH by supplying a static power source to the plurality of coils 151, 152, and 153. The electromagnet 150 and the third power supply 160 may be collectively referred to as a magnetic field control device.

The exhaust device 170 may depressurize the chamber space by discharging the process gas in the chamber space CH externally. For example, the exhaust device 170 may include a pump device.

The optical interface 181 may acquire or receive light output from the chamber space CH for process monitoring. For example, the optical interface 181 may be referred to as a view port. In addition, the light may include a light component of a specific wavelength emitted when atoms in an excited state in the plasma PLA is relocated to a lower energy level.

The spectrometer 182 may analyze light acquired from the optical interface 181. For example, the spectrometer 182 may perform optical emission spectroscopy (OES) analysis to separate the light acquired from the optical interface 181 by wavelength, and may perform process monitoring, based on the light component of specific wavelength(s).

The control unit 190 may control various operations such as the gas supply device 120, the first power supply 131, the second power supply 141, the third power supply 160, the exhaust device 170, the spectrometer 182, and the like. The control unit 190 can include digital and/or analog circuitry, and can include a computing device configured to perform the control operations described herein.

To have uniform quality of a semiconductor device manufactured on the substrate W by the plasma process, uniform process distribution is required. Process distribution may refer to distribution of semiconductor process result values. For example, the process distribution may include distribution of an etching rate for each region of the substrate W, distribution of a critical dimension (CD) for each region of the substrate W, or the like.

When the plasma distribution for each region of the chamber space CH is not uniform, the process distribution for each region of the substrate W on which the plasma process was performed may also become non-uniform. Therefore, in order for the process distribution in each region of the substrate W to be uniform, the plasma distribution in each region of the chamber space CH may be precisely controlled.

The plasma processing device 100 may control plasma distribution for each region of the chamber space CH by forming a magnetic field in the chamber space CH using the electromagnet 150. A Lorentz force caused by the magnetic field may act from a central portion of the chamber space CH toward a peripheral portion of the chamber space CH, and electrons may move to the peripheral portion of the chamber space CH. Therefore, when controlling the plasma distribution based only on the Lorentz force, the plasma distribution may be controlled only in a manner in which plasma density in the central portion of the chamber space CH decreases, and it may be difficult to uniformly control the plasma density.

According to some implementations, the plasma processing device 100 increases the efficiency of generating plasma in the central portion of the chamber space CH by generating magnetic resonance in the central portion. Accordingly, the plasma processing device 100 may control plasma distribution in a manner in which plasma density in the central portion of the chamber space CH increases, and as a result, a control range of plasma distribution may be improved. In addition, the plasma processing device 100 may uniformly control the process distribution even when the process result value in the central portion of the chamber space CH has low process distribution.

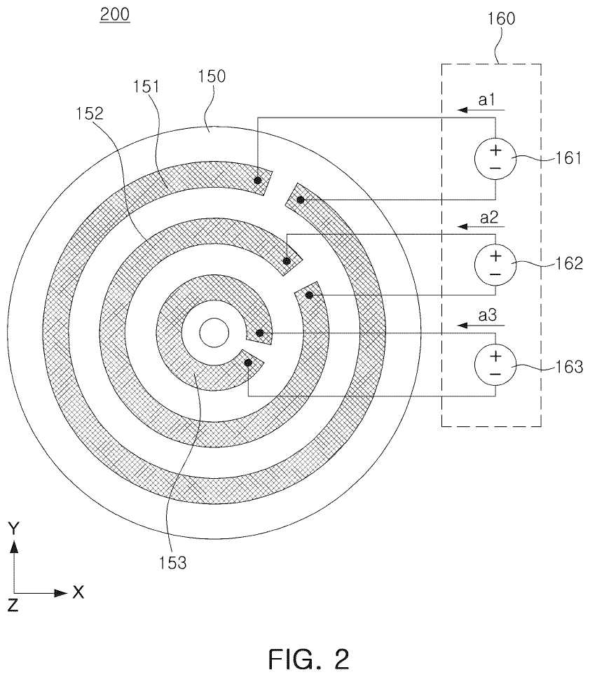

Hereinafter, a structure of the magnetic field control device will be described in detail with reference to FIGS. 2 to 4. Plasma density control by the Lorentz force will be first described.

As shown in FIG. 2, a magnetic field control device 200 may include an electromagnet 150 and a third power supply 160, as described with reference to FIG. 1.

The electromagnet 150 may include a plurality of coils 151, 152, and 153. The plurality of coils 151, 152, and 153 may be arranged along concentric circles on an X-Y plane centered on a central axis passing through a center of the substrate W in a third direction Z. The central axis may, though need not, coincide with a central axis of a chamber space CH described with reference to FIG. 1, and may further, though need not, pass through a center of the upper electrode 130 and a center of the electrostatic chuck 140.

In some implementations, the electromagnet 150 includes a cylindrical yoke in the plurality of coils 151, 152, and 153. The electromagnet 150 may further include a mold portion supporting the plurality of coils 151, 152, and 153.

In the example of FIG. 2, the plurality of coils 151, 152, and 153 are illustrated as partially open annular shapes, but, in some implementations, the plurality of coils 151, 152, and 153 may be implemented as spring type coils wound around the central axis.

The third power supply 160 may independently control currents a1, a2, and a3 flowing through the plurality of coils 151, 152, and 153. For example, the third power supply 160 may include a first power source 161 applying a first current a1 to a first coil 151, a second power source 162 applying a second current a2 to a second coil 152, and a third power source 163 applying a third current a3 to a third coil 153.

When the currents a1, a2, and a3 are applied to the plurality of coils 151, 152, and 153, a magnetic field may be formed around the plurality of coils 151, 152, and 153. A Lorentz force may act on electrons included in plasma PLA by the currents a1, a2, and a3 flowing in the plurality of coils 151, 152, and 153 and the magnetic field formed in the chamber space CH disposed below the plurality of coils 151, 152, and 153, and a distribution of the plasma PLA may be controlled as the electrons move by the Lorentz force.

FIG. 3 is a view illustrating movement of electrons due to a magnetic field in a plasma processing device. As shown in FIG. 3, the plasma processing device 100 includes a chamber space CH, an upper electrode 130, an electrostatic chuck 140, a substrate W, and an electromagnet 150 in a plasma processing device 100, having characteristics as described with reference to FIG. 1. To control electrons e⁻ in the chamber space CH, the plasma processing device 100 may apply a magnetic field toward the chamber space CH by applying a current to a plurality of coils 151, 152, and 153. FIG. 3 illustrates a direction of an electric field E in a cross-section of a third coil 153.

Due to the current applied to the plurality of coils 151, 152, and 153, the magnetic field may be formed around the plurality of coils 151, 152, and 153. The magnetic field may be formed in a direction perpendicular to the electric field E, and may be formed to surround the plurality of coils 151, 152, and 153.

FIG. 3 illustrates directions of some components of a magnetic field B. In the magnetic field B, directional components spreading from a central axis of a chamber to a peripheral portion may be dominant, as illustrated in FIG. 3. When the electric field E and the magnetic field B in directions perpendicular to each other are applied to the electrons e⁻, the Lorentz force may act on the electrons e⁻ in a direction corresponding to the cross product of the electric field E and magnetic field B. Electron drift may occur in which electrons e⁻, driven by the Lorentz force, move while rotating in a spiral shape, based on a direction of the magnetic field B. The electron drift may be referred to as E×B drift. Due to E×B drift, the electrons e⁻ may be concentrated in a peripheral portion of the chamber space CH, and positive ions may also move along with the electrons e.

As a result, when distribution of plasma PLA is controlled based only on the Lorentz force, the distribution of plasma PLA may be controlled in a manner such that plasma density in the peripheral portion of the chamber space CH is strengthened and plasma density in a central portion of the chamber space CH is weakened.

When the distribution of plasma PLA is controlled in only one manner, as described with reference to FIG. 3, it may be difficult to uniformly control process distribution in an environment having various process distributions, depending on the process environment.

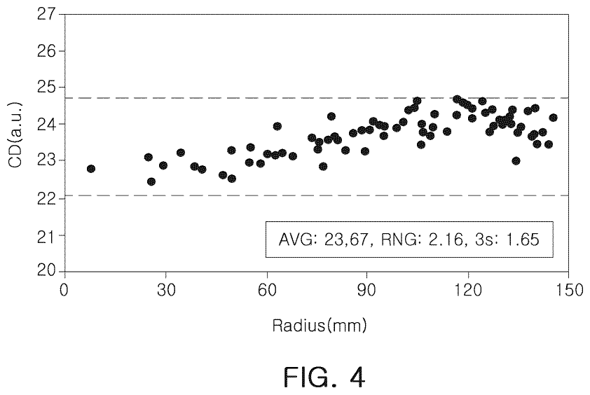

For example, FIG. 4 illustrates an example of process distribution of a plasma processing device. The graph in FIG. 4 illustrates distribution of critical dimension (CD) according to a radius from a central axis of a substrate W. The CD in FIG. 4 represents CD when a magnetic field is not formed by a magnetic field control device.

For example, a position having a radius of ‘0’ represents a center of the substrate W, and a position having a radius of ‘150’ represents an edge of the substrate W. Referring to FIG. 4, in process distribution, the CD may decrease toward the center of the substrate W, and the CD may increase toward the edge of the substrate W. The CD may have a positive correlation with an etching rate. For example, in a region not sufficiently etched, a width between adjacent patterns may not be wide enough. In order for the process distribution to be even, the CD may need to be adjusted upward by adjusting the etching rate in a central portion of the substrate W upward.

When a density of the plasma PLA is controlled only depending on Lorentz force, as described with reference to FIG. 3, control may be limited to decreasing the density of the plasma PLA in a central portion of the chamber space CH and to increasing the density of the plasma PLA in a peripheral portion of the chamber space CH. Therefore, it may be difficult to evenly correct the process distribution illustrated in FIG. 4.

According to some implementations of the present disclosure, a magnetic field control device is not limited to controlling the density of plasma PLA by controlling movement of electrons by applying Lorentz force to electrons in the chamber space CH. The density of plasma PLA may be controlled by increasing efficiency of plasma generation by generating magnetic resonance in the central portion of the chamber space CH, to generate plasma PLA in the central portion.

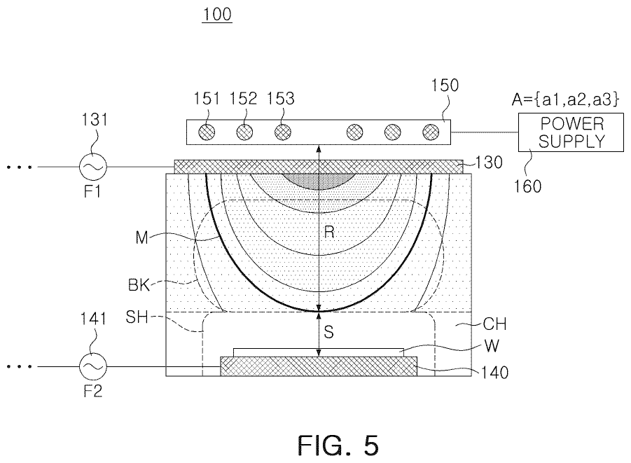

Hereinafter, methods of controlling a magnetic field of a plasma processing device according to some implementations will be described in detail with reference to FIGS. 5 to 8.

As shown in FIG. 5, a plasma processing device 100 includes a chamber space CH, an upper electrode 130, a first power supply 131, an electrostatic chuck 140, a second power supply 141, a substrate W, an electromagnet 150, and a third power supply 160, as described with reference to FIG. 1.

The first power supply 131 may provide a first high-frequency power source having a first frequency F1 to the upper electrode 130, and the second power supply 141 may provide a second high-frequency power source having a second frequency F2 to the electrostatic chuck 140.

As explained with reference to FIG. 1, plasma PLA may be formed by exciting a process gas by the first high-frequency power source applied to the upper electrode 130 or the second high-frequency power source applied to a lower electrode, either alone or simultaneously. A plasma process may be performed on the substrate W by accelerating positive ions included in the plasma PLA by the second high-frequency power source.

Plasma may include electrons, positive ions, and neutrons. The electrons may be much lighter than the positive ions, and may have higher mobility than the positive ions. Therefore, the electrons included in the plasma may move to the electrostatic chuck 140 faster than the positive ions, thereby charging the electrostatic chuck 140 as a negative electrode and pushing out the electrons. As a result, the positive ions and the neutrons mainly remain around the electrostatic chuck 140, and a region mainly containing the positive ions and the neutrons may be referred to as a sheath region SH. Due to the positive ions in the sheath region SH and the electrons in the electrostatic chuck 140, a voltage may rapidly drop in the sheath region SH. An electric field formed in the sheath region may accelerate the positive ions in the sheath region, and may generate high kinetic energy. In some implementations, an etching process is performed on the substrate W when the positive ions having high energy collide with the substrate.

A bulk plasma region BK may include electrons, positive ions, and neutrons. The electrons in the bulk plasma region BK may oscillate at a frequency determined by the first high-frequency power source and the second high-frequency power source. For example, the electrons may oscillate at the first frequency F1, which may be a frequency of the first high-frequency power source for exciting the process gas, or at the second frequency F2, which may be a frequency of the second high-frequency power source. Additionally, a frequency at which electrons oscillate may further include a common multiple of the first frequency F1 and the second frequency F2.

Coils 151, 152, and 153 included in the electromagnet 150 may form a magnetic field in a chamber space CH by currents a1, a2, and a3 applied from the third power supply 160. FIG. 5 illustrates a distribution of the magnetic field formed in the chamber space CH according to a magnetic flux density. In the chamber space CH, a region illustrated in relatively dark shade has a relatively high magnetic flux density, and a region illustrated in relatively light shade has a relatively low magnetic flux density. Magnetic flux lines representing positions with the same magnetic flux density in the chamber space CH are illustrated in the form of contour lines. In FIG. 5, an indication of the magnetic field that may be formed in the sheath region SH is omitted.

Referring to FIG. 5, the magnetic flux density of the magnetic field formed in the chamber space CH varies based on position. The magnetic flux density of the magnetic field may be changed depending on a magnitude and a direction of the currents a1, a2, and a3, but may be generally higher toward an upper portion of the chamber space CH and toward a central axis of the chamber space CH.

As explained with reference to FIG. 3, the electrons included in the plasma PLA may rotate by the Lorentz force due to currents applied to the coils 151, 152, and 153 and magnetic fields formed by the coils 151, 152, and 153. A rotation period of the electrons may be determined depending on the magnetic flux density of the magnetic field. For example, the rotation period of the electrons may be changed depending on a position of the chamber space CH.

When an oscillation period of the electrons based on the first high-frequency power source matches a rotation period of the electrons based on the magnetic flux density of the magnetic field, magnetic resonance may occur. For example, an amplitude of electrons oscillating at a certain period may increase significantly, as the electrons continuously receive an external force having the same frequency as the oscillation period. Therefore, the average kinetic energy of the electrons may increase due to the magnetic resonance. When the kinetic energy of electrons increases, temperatures of the electrons may increase, increasing the efficiency of generating plasma (efficiency of plasma generation).

Since the rotation period of the electrons varies depending on a position of the chamber space CH, magnetic resonance may occur in a local region in the chamber space CH in which the rotation period and the oscillation period of the electrons match, and the efficiency of generating plasma in this region may increase. In FIG. 5, example magnetic flux lines are illustrated as bold lines representing positions with magnetic flux densities M in which magnetic resonance may occur.

As illustrated in FIG. 5, when magnetic resonance occurs in a position in which a central axis of the chamber space CH passing through a center of the substrate W in a vertical direction meets a boundary of the sheath region SH, a density of plasma in this position may increase, and when performing a plasma process, a large amount of positive ions may be irradiated to/directed to the center of the substrate W. As a result, process result values at the center of the substrate W may be controlled upward.

According to some implementations, the plasma processing device 100 controls the currents a1, a2, and a3 to have a magnetic flux density in which the rotation period of the electrons matches the oscillation period of the electrons, at a distance R ranging from centers of the coils 151, 152, and 153 to a position in which the boundary of the sheath region SH meets, based on a thickness S of the sheath region.

According to some implementations, the plasma processing device 100 controls upward process result values in a central portion of the substrate W by increasing the density of plasma at a target position at which the central axis of the chamber space CH and the boundary of the sheath region SH meet. Therefore, a control range of process distribution may be expanded, and it may be more easy to adjust the process distribution to be uniform for each region of the substrate W.

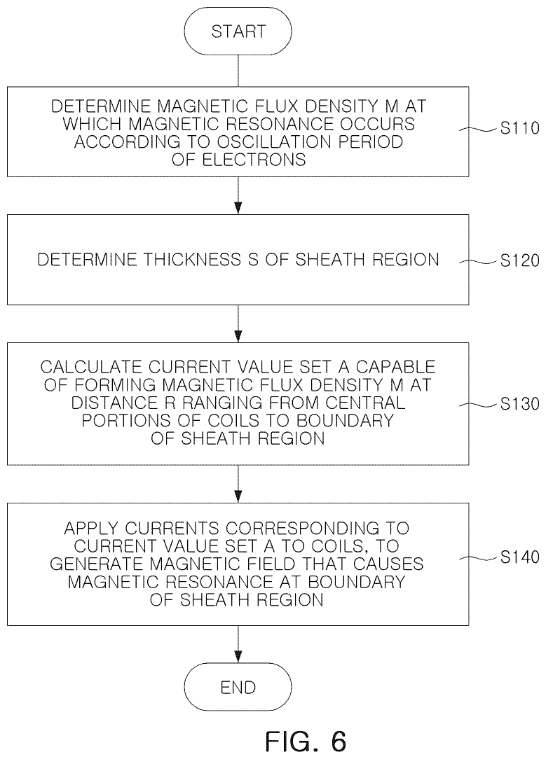

FIG. 6 is a flowchart illustrating a method of controlling a magnetic field. The method of controlling the magnetic field may include S110 to S140, and S110 to S140 may be performed by a control unit 190, as described with reference to FIG. 1.

In S110, the control unit 190 may determine a magnetic flux density M at which electrons may cause or experience magnetic resonance, based on an oscillation period of the electrons. As explained with reference to FIG. 5, the oscillation period of the electrons may be influenced by a first high-frequency power source and/or a second high-frequency power source. For example, the oscillation period of the electrons may have at least one of a first frequency F1 component, a second frequency F2 component, or a common multiple of a first frequency F1 and a second frequency F2. In addition, a rotation period of the electrons may be determined based on a magnetic flux density of a magnetic field, and the rotation period of the electrons may be derived from the well-known Lorentz force formula. The control unit 190 may determine a magnetic flux density M at which the rotation period of the electrons matches the oscillation period of the electrons.

In S120, the control unit 190 may determine a thickness S of a sheath region. The thickness S of the sheath region may mean a distance ranging from an upper surface of an electrostatic chuck 140 to a boundary of the sheath region along a central axis of the chamber space CH or a central axis of the substrate W. The thickness S of the sheath region may be calculated based on process conditions, such as at least one of a temperature of the chamber space CH, a potential difference between the boundary of the sheath region SH and the electrostatic chuck 140, a pressure of the chamber space CH, or a flow rate of a process gas.

In some implementations, the control unit 190 adjusts calculated values of the thickness S of the sheath region, based on process results. For example, the control unit 190 may control currents a1, a2, and a3, based on the calculated values, and may adjust the calculated values of the thickness S of the sheath region, based on results of performing a plasma process.

In S130, the control unit 190 may calculate a current value set A capable of forming a magnetic flux density M capable of causing magnetic resonance at a distance R that is the distance from a central portion of the coils to the boundary of the sheath region SH. For example, using the Biot-Savart law, a magnetic flux density for a position may be calculated based on (i) a distance of the position from the coils 151, 152, and 153, and (ii) the currents a1, a2, and a3 applied to coils 151, 152, and 153. The control unit 190 may calculate a current value set A, which may be a combination of values of currents a1, a2, and a3 capable of forming a magnetic flux density M at the distance R ranging from central portions of the coils to the boundary of the sheath region SH (for example, at the boundary of the sheath region SH and along the central axis), using the Biot-Savart law

In S140, the control unit 190 may control a third power supply 160 such that the currents a1, a2, and a3 flowing through the coils 151, 152, and 153 have current values included in the current value set A, to generate a magnetic field that causes magnetic resonance at the boundary of the sheath region SH (e.g., at the boundary of the sheath region SH along the central axis).

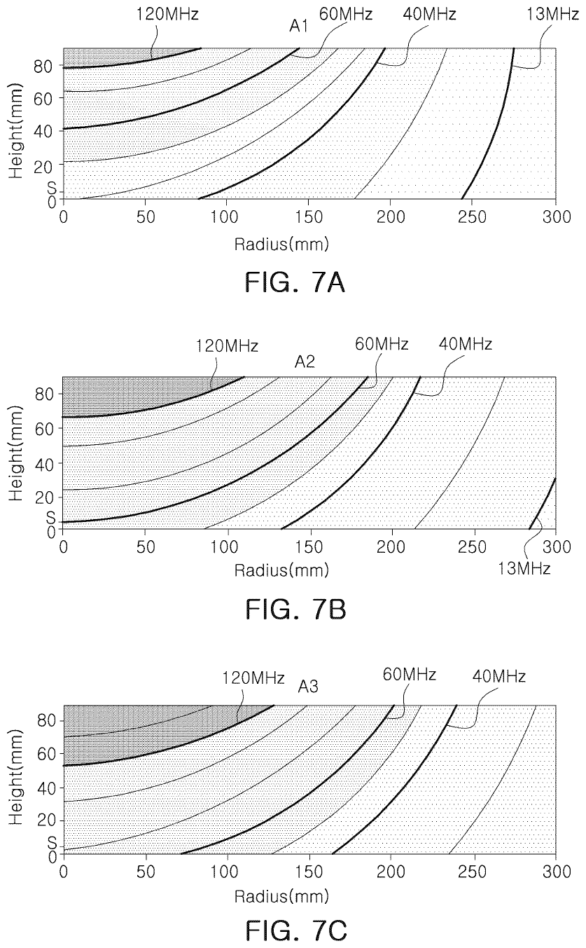

FIGS. 7A to 7C illustrate magnetic field distribution according to a position in a chamber space when currents are applied to coils using different sets of current values. In the graphs of FIGS. 7A to 7C, the horizontal axis represents a distance (radius) from a central axis of a chamber space CH. The vertical axis represents a height in the chamber space CH, in reference to an upper surface of an electrostatic chuck. On the vertical axis, a thickness S of a sheath region is displayed, based on the upper surface of the electrostatic chuck.

FIG. 7A illustrates magnetic field distribution when a first current value set A1 is applied to the coils. Regions illustrated in a relatively dark shade in the graph have a relatively high magnetic flux density, and regions illustrated in a relatively light shade have a relatively low magnetic flux density. Magnetic flux lines representing positions having the same magnetic flux density are illustrated. In particular, a magnetic flux line illustrated as a thick line illustrates a position of the chamber space CH having a magnetic flux density in which a oscillation period of electrons and a rotation period of the electrons match for oscillation periods of 13 MHz, 40 MHZ, 60 MHz, and 120 MHz.

FIG. 7B illustrates magnetic field distribution when a second current value set A2 is applied to the coils. In FIG. 7B, shades and magnetic flux lines are illustrated according to a magnetic flux density, like FIG. 7A. In particular, a magnetic flux line illustrated as a thick line illustrates a position of the chamber space CH having a magnetic flux density in which a oscillation period of electrons and a rotation period of the electrons match for oscillation periods of 13 MHz, 40 MHz, 60 MHz, and 120 MHz.

FIG. 7C illustrates magnetic field distribution when a third current value set A3 is applied to the coils. In FIG. 7C, shades and magnetic flux lines according to a magnetic flux density are illustrated, similar to FIGS. 7A and 7B. In particular, a magnetic flux line illustrated as a thick line illustrates a position of the chamber space CH having a magnetic flux density in which a oscillation period of electrons and a rotation period of the electrons match for oscillation periods of 40 MHz, 60 MHz, and 120 MHz.

The oscillation period of the electrons may be determined according to a frequency of a high-frequency power source applied to at least one of an upper electrode 130 or a lower electrode. For example, when a first high-frequency power source having a first frequency F1 is applied alone to the upper electrode 130, the oscillation period of the electrons may include a first frequency F1 component. Also, when a second high-frequency power source having a second frequency F2 is applied alone to the lower electrode including the electrostatic chuck 140, the oscillation period of the electrons may include a second frequency F2 component. When the first high-frequency power source and the second high-frequency power source are applied simultaneously, the oscillation period of the electrons may include the first frequency F1 component, the second frequency F2 component, and a common multiple of the first frequency F1 and the second frequency F2.

For example, when the first frequency F1 is 60 MHz and the second frequency F2 is 40 MHz, and the first high-frequency power source and the second high-frequency power source are applied at the same time, the oscillation period of the electrons may include 60 MHz, 40 MHZ, and a common multiple of 120 MHz. When a magnetic flux line corresponding to 60 MHz, a magnetic flux line corresponding to 40 MHz, or a magnetic flux line corresponding to 120 MHz passes through a target position in which a central portion of the chamber space CH and a boundary S of the sheath region meet, magnetic resonance may occur at the target position.

In examples of FIGS. 7A and 7C, since none of a magnetic flux line corresponding to 60 MHz, a magnetic flux line corresponding to 40 MHz, and a magnetic flux line corresponding to 120 MHz pass through the target position at the boundary of the sheath region, magnetic resonance does not occur at the target position. In an example of FIG. 7B, a magnetic flux line corresponding to 60 MHz passes through the target position, and magnetic resonance occurs at the target position.

Therefore, based on the oscillation period of the electrons determined by at least one of the first high-frequency power source or the second high-frequency power source, the second current value set A2 may be selected such that magnetic resonance occurs at a position at which the central portion of the chamber space CH and the boundary S of the sheath region meet.

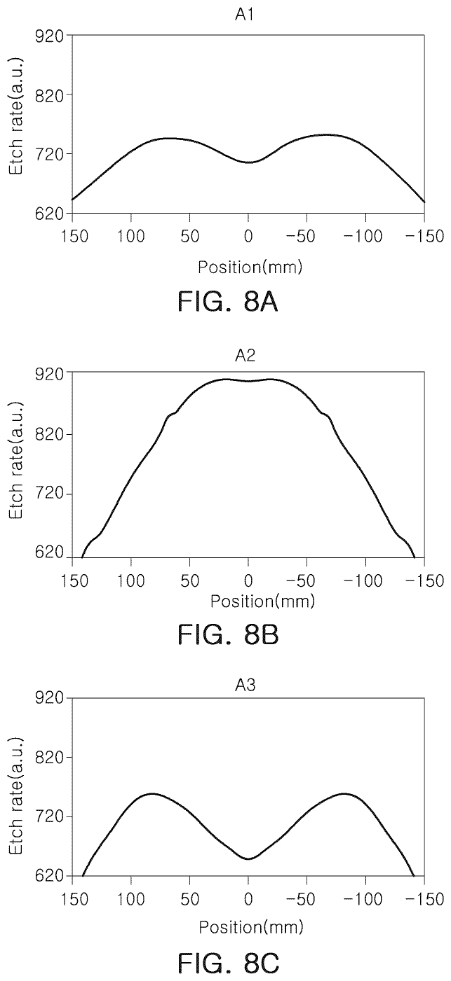

FIGS. 8A to 8C illustrate an etching rate according to a position of a substrate W when a first high-frequency power source having a frequency of 60 MHz is applied alone to an upper electrode 130 and currents are applied to coils using different current value sets A1, A2, and A3, as illustrated in FIGS. 7A to 7C. In graphs of FIGS. 8A to 8C, a horizontal axis represents a relative position from a central axis of the substrate W, and a vertical axis represents the etching rate. On the horizontal axis, ‘0’ may represent a central portion of the substrate W, and ‘−150’ and ‘150’ may represent both end portions of the substrate in any direction, parallel to an upper surface of the substrate.

FIG. 8A illustrates etching rate distribution when a first current value set A1, as described with reference to FIG. 7A, is applied to the coils. Referring to FIG. 7A, a magnitude of a magnetic field formed by the coils may not be sufficient to cause magnetic resonance on a boundary of a sheath region, and a magnetic flux line corresponding to 60 MHz passes through a position spaced approximately 40 mm away from an electrostatic chuck 140 in a central portion of a chamber space CH. Plasmas generated due to magnetic resonance in a position spaced apart from the boundary S of the sheath region may move to a peripheral portion of the substrate W due to E×B drift, and may participate less in plasma processing of the central portion of the substrate W. Therefore, in the substrate W, an etching rate of the central portion may be lower than an etching rate of the peripheral portion.

FIG. 8B illustrates etching rate distribution when a second current value set A2, as described with reference to FIG. 7B, is applied to the coils. Referring to FIG. 7B, a magnitude of a magnetic field formed by the coils is appropriate to generate magnetic resonance at a target position at which a central portion of a chamber space CH and a boundary S of a sheath region meet. For example, a magnetic flux line corresponding to 60 MHz passes through the target position. A large amount of plasma generated due to magnetic resonance at the target position may actively participate in plasma processing of the central portion of the substrate W, and, in the substrate W, an etching rate of the central portion may be higher than an etching rate of the peripheral portion.

FIG. 8C illustrates etching rate distribution when a third current value set A3, as described with reference to FIG. 7C, is applied to the coils. Referring to FIG. 7C, a magnitude of a magnetic field formed by the coils is excessive to cause magnetic resonance in a position at which a central portion of a chamber space CH and a boundary S of a sheath region meet, and a magnetic flux line corresponding to 60 MHz passes through a position in which the boundary of the sheath region S and a peripheral portion of the chamber space CH meet. Therefore, magnetic resonance may occur at the position in which the peripheral portion of the chamber space CH and the boundary S of the sheath region meet. As a result, an etching rate of the central portion of the substrate W in FIG. 8C may be lower than an etching rate of the central portion of the substrate W in FIG. 8A.

Referring to FIGS. 8A to 8C, the second current value set A2, for which magnetic resonance occurs at a position at which the central portion of the chamber space CH and the boundary S of the sheath region meet, may be selected. As a result, process result values in the central portion of the substrate W may be controlled upward.

In some implementations, the control unit 190, as described with reference to FIG. 1, may control current values flowing in the coils 151, 152, and 153, as illustrated in FIGS. 7A to 7C. For each of a plurality of current value sets including various combinations of currents, a resonance position, having a magnetic flux density for which the oscillation period of the electrons and the rotation period of the electrons match, may be determined for each oscillation period of the electrons (e.g., 120 MHz, 60 MHz, etc.). Then, the control unit 190 may select a current value set for which the target position matches the resonance position, among the plurality of current value sets, and may control currents corresponding to the current value set to flow in the coils 151, 152, and 153, to generate magnetic resonance at the target position.

A thickness of the sheath region SH and/or a magnetic flux density for each position of the chamber space CH may change depending on variability (e.g., errors) in a process environment. Depending on the variability in the process environment, the current value set for generating magnetic resonance at the position at which the boundary S of the sheath region and the central axis of the chamber space CH meet may be changed.

According to some implementations, a plasma processing device 100 monitors a plasma process in real time, and may change the current value set for generating magnetic resonance according to monitoring results.

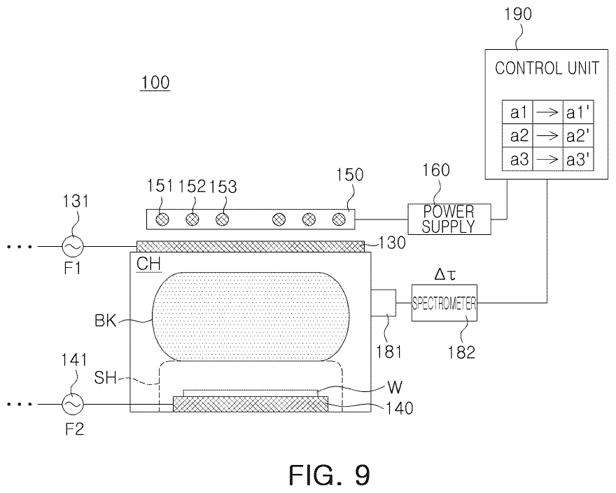

For example, as shown in FIG. 9, a plasma processing device 100 includes a chamber space CH, an upper electrode 130, a first power supply 131, an electrostatic chuck 140, a second power supply 141, a substrate W, an electromagnet 150, a third power supply 160, an optical interface 181, a spectrometer 182, and a control unit 190, as described with reference to FIG. 1.

As described with reference to FIGS. 5 to 8, the plasma processing device 100 may control a magnetic field formed by the electromagnet 150 to generate magnetic resonance at a target position at which a central axis of the chamber space CH and a boundary of a sheath region meet. Moreover, the magnetic field formed may be controlled. For example, the third power supply 160 may control currents a1, a2, and a3 to have current values calculated to cause the magnetic resonance at the target position. As discussed above, the magnetic flux density can depend on at least an oscillation period of electrons, which may be determined by at least one of a first frequency F1 and a second frequency F2.

In some cases, even though the calculated currents a1, a2, and a3 flow through the coils 151, 152, and 153, magnetic resonance may not occur at the target position in the chamber space CH due to a change in process environment. For example, there may be a fine difference in process environment in different chambers, and the process environment may be changed over time even in the same chamber. Depending on the process environment, a thickness of the sheath region SH or the like may differ from the calculated or assumed one, and, when the currents a1, a2, and a3 are applied, the position at which magnetic resonance actually occurs may deviate from the target position. When the position in which magnetic resonance actually occurs is different from the target position, it may be difficult to effectively control process distribution in a central portion of the substrate W.

According to some implementations, the plasma processing device 100 perform OES monitoring using the spectrometer 182, and adjusts values of currents applied to the coils 151, 152, and 153 according to the monitoring results, to effectively control process distribution.

Plasma may emit light with a unique wavelength, depending on a type of plasma gas or a type of a by-product participating in a plasma process. The optical interface 181 may include an optical window through which light in the chamber space CH may be transmitted. The optical interface 181 may monitor light generated from the plasma in the chamber space CH. Additionally, the spectrometer 182 may split the light according to a wavelength, and may then monitor an intensity of the light for each wavelength.

According to some implementations, the control unit 190 monitors an intensity of light at a target wavelength corresponding to a unique wavelength of light emitted from the by-product, and, when a measured value of the intensity of light is different from a reference value, values of the currents a1, a2, and a3 flowing in the coils 151, 152, and 153 may be adjusted in a manner such that a difference Δτ between the measured value and the reference value decreases. The control unit 190 may control the third power supply 160 such that adjusted currents a1′, a2′, and a3′ flow in the coils 151, 152, and 153, to control to generate magnetic resonance at the target position.

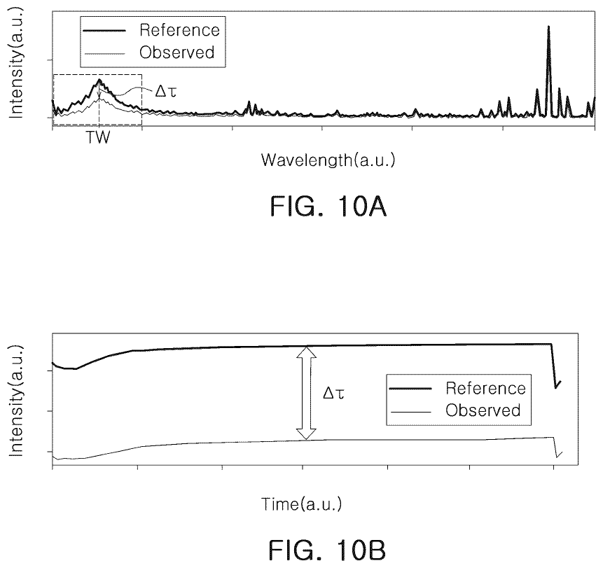

FIGS. 10A and 10B illustrate OES monitoring results of a spectrometer 182, as described with reference to FIG. 9. A graph in FIG. 10A illustrates an intensity of light by wavelength at a certain point in time. As previously explained, light having a unique wavelength may be emitted, depending on a type of by-product participating in a plasma process. The intensity of light at the unique wavelength may be changed, depending on an amount of the by-product generated in the plasma process. Therefore, when the unique wavelength is determined as a target wavelength TW and the intensity of light at the target wavelength TW is analyzed, it may be determined whether a process reaction has been actively performed.

When magnetic resonance occurs at a target position in which a central portion of a chamber space CH and a boundary of a sheath region SH meet, a large amount of plasma may be generated at the target position, and an active process reaction may occur in a central portion of a substrate W. Due to the active process reaction, a large amount of a by-product may be generated, and an intensity of light at the target wavelength TW may be relatively large. When magnetic resonance does not occur at the target position, an intensity of light at the target wavelength TW may be relatively small.

According to some implementations, a plasma processing device 100 determines the intensity of light at the target wavelength TW when magnetic resonance occurs at the target position as a reference value, and may adjust current values of coils 151, 152, and 153, based on the difference value Δτ between the reference value and the measured value (observed value).

The reference value may be determined in advance. As a first example, current values determined in the same manner, as described with reference to FIGS. 5 to 8, may be applied to coils of a plasma processing device in an experimental environment, and a reference value may be determined by analyzing an intensity of light at a target wavelength TW using an optical interface 181 and a spectrometer 182 of the plasma processing device. As a second example, a reference value may be determined by applying the current values to simulate an intensity of light measured at a target wavelength TW.

The graph in FIG. 10B illustrates an intensity of light at the target wavelength over time. A process environment of the plasma processing device 100 may differ from an experimental environment, and the process environment may be changed, depending on time. Therefore, a difference value Δτ may occur between the reference value and the measured value.

As illustrated in FIG. 10B, the spectrometer 182 may monitor the intensity of light at the target wavelength over time. According to some implementations, the plasma processing device 100 may monitor the intensity of light at the target wavelength in real-time while adjusting the current values of the coils 151, 152, and 153, to determine current values minimizing the difference value Δτ.

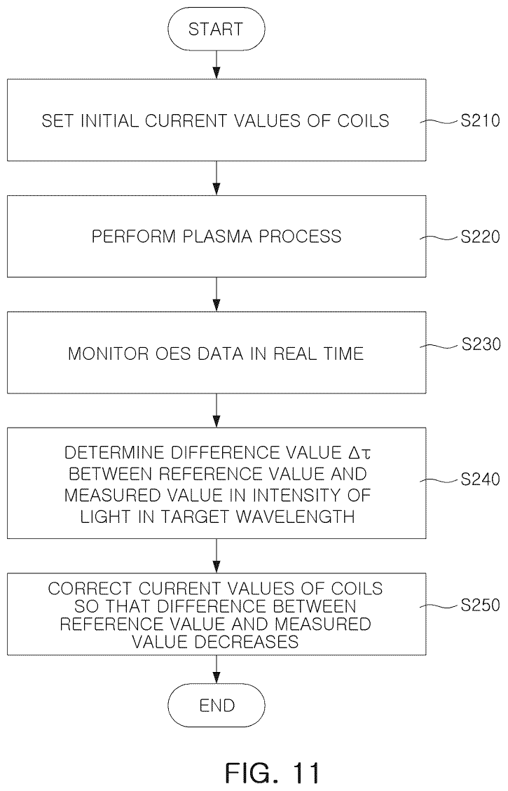

FIG. 11 is a flowchart illustrating a method of controlling a magnetic field according to some implementations. The method includes S210 to S240, and S210 to S240 may be performed by a control unit 190, as described with reference to FIGS. 1 and 9.

In S210, the control unit 190 sets initial current values of coils 151, 152, and 153. For example, the control unit 190 may set current values calculated in the same manner as described with reference to FIGS. 5 to 8, as the initial current values of the coils 151, 152, and 153.

In S220, the control unit 190 controls a plasma processing device 100 to perform a plasma process, based on the set initial current values. As the plasma process progresses, a by-product may be generated in a chamber space CH.

In S230, the control unit 190 monitors OES data in real time using a spectrometer 182. Specifically, the control unit 190 may determine a unique wavelength generated by the by-product as a target wavelength, and may monitor an intensity of light at the target wavelength over time.

In S240, the control unit 190 determines a difference value Δτ between a reference value and a measured value in the intensity of light in a target wavelength.

In S250, the control unit 190 corrects the current values of the coils 151, 152, and 153 such that the difference between the reference value and the measured value decreases.

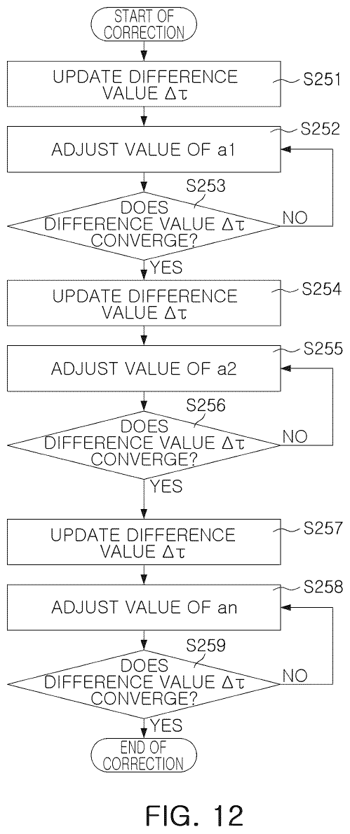

FIG. 12 is a flowchart detailing a method of correcting current values according to some implementations.

An operation of correcting current values, S250, as described with reference to FIG. 11, may include S251 to S259. S251 to S259 represent operations of controlling a difference value Δτ between a reference value and a measured value, so as to minimize the difference value, while adjusting current values of coils 151, 152, and 153 (e.g., one by one).

In S251, a control unit 190 updates a difference value Δτ determined in real time.

In S252, the control unit 190 adjusts a first current value a1 of a first coil 151. For example, the control unit 190 may monitor whether the difference value Δτ decreases while increasing or decreasing the first current value a1, and may adjust the first current value a1 in a manner in which the difference value Δτ decreases.

In S253, the control unit 190 determines whether the difference value Δτ converges to a minimum value by adjusting the first current value a1. When the difference value Δτ does not converge (“No” in S253), the control unit 190 may repeatedly perform S252 and S253 until the difference value Δτ converges to the minimum value. When the difference value Δτ converges to the minimum value and the difference value Δτ no longer changes in a decreasing manner (“Yes” in S253), the control unit 190 updates the first current value a1 to a first current value a1′ at which the difference value Δτ converges to the minimum value.

In S254, the control unit 190 updates a difference value Δτ determined in real time.

In S255, the control unit 190 adjusts a second current value a2 of a second coil 152. Similar to what was described in S252, the control unit 190 may monitor whether the difference value Δτ decreases while increasing or decreasing the second current value a2, and may adjust the second current value a2 in a manner such that the difference value Δτ decreases.

In S256, the control unit 190 determines whether the difference value Δτ converges to a minimum value by adjusting the second current value a2. When the difference value Δτ does not converge (“No” in S256), the control unit 190 may repeatedly perform S255 and S256 until the difference value Δτ converges to the minimum value. When the difference value Δτ converges to the minimum value (“Yes” in S256), the control unit 190 may update the second current value a2 to a second current value a2′ when the difference value Δτ converges to the minimum value.

In S257, the control unit 190 updates a difference value Δτ determined in real time.

In S258, the control unit 190 adjusts a third current value a3 of a third coil 153. Similar to what was described in S252, the control unit 190 may monitor whether the difference value Δτ decreases while increasing or decreasing the third current value a3, and may adjust the third current value a3 such that the difference value Δτ decreases.

In S259, the control unit 190 determines whether the difference value Δτ converges to a minimum value by adjusting the third current value a3. When the difference value Δτ does not converge (“No” in S259), the control unit 190 may repeatedly perform S258 and S259 until the difference value Δτ converges to the minimum value. When the difference value Δτ converges to the minimum value (“Yes” in S259), the control unit 190 may update the third current value a3 to a third current value a3′ when the difference value Δτ converges to the minimum value.

When the difference value Δτ converges to ‘0’ or another target value or range while performing S251 to S259, the control unit 190 may end the correction, and may update the current values of the coils 151, 152, and 153 to current values of the coils 151, 152, and 153 when the difference value Δτ converge to ‘0’ or the other target value or range.

Referring to FIG. 9, among the plurality of coils disposed in concentric circles centered on the central axis of the chamber space CH in the electromagnet 150, the first coil 151 may be a coil disposed in the outermost concentric circle, the second coil 252 may be a coil disposed in a middle concentric circle, and the third coil 253 may be a coil disposed in the innermost concentric circle. When an amount of change in current values at the first to third coils 151 to 153 are the same, a change in magnetic flux density due to the first coil 151 may be the smallest, and a change in magnetic flux density may increase in order from the second coil 152 to the third coil 153.

According to some implementations, in S251 to S259, the control unit 190 perform current correction in a predetermined order from the outermost coil to the innermost coil. That is, the control unit 190 may select at least one of the plurality of coils in order of decreasing coil radius, and repeat the operation for the at least two of the plurality of coils. For example, the control unit 190 may preferentially perform fine adjustment of a magnetic flux density, and when magnetic resonance cannot be achieved by the fine adjustment, the magnetic flux density may be adjusted in a wider range. However, the present disclosure is not limited thereto, and the control unit 190 may perform coarse-fine tuning by performing current correction in order from the innermost coil to the outermost coil.

According to some implementations, as described with reference to FIGS. 9 to 12, a plasma processing device 100 may generate magnetic resonance at a target position despite errors in a process environment or changes in the process environment over time, to control plasma density in a manner in which the plasma density increases in the central portion of the substrate W. As a result, a distribution control range of the plasma processing device 100 may be improved, and the improved distribution control range may be maintained despite changes in the process environment. For example, tool-to-tool matching (TTTM) of the plasma processing device may be improved, and constancy of process distribution may be improved.

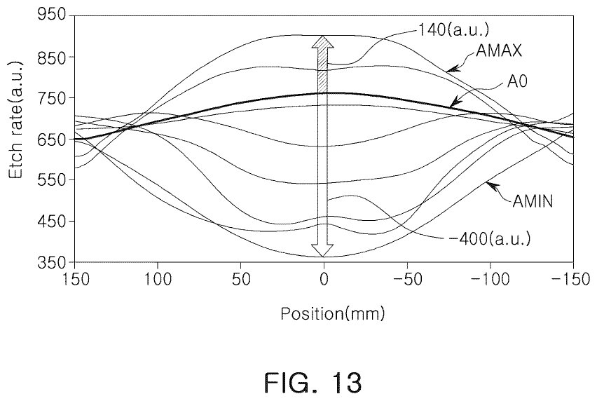

FIG. 13 illustrates process parameters that result from applying current value sets having various combinations of current values to coils 151, 152, and 153, as described with reference to FIGS. 5 and 9, in a plasma processing device 100. In the graph, the horizontal axis represents a relative position from a central axis of a substrate W, and the vertical axis represents an etching rate. On the horizontal axis, ‘0’ represents a central portion of the substrate W, and ‘-150’ and ‘150’ represent both end portions of the substrate in any direction, parallel to an upper surface of the substrate.

A reference distribution map A0 illustrated in a thick line in FIG. 13 represents an example distribution map when no current is applied to the coils 151, 152, and 153. A lowest distribution map (AMIN) represents an example distribution map in which an etching rate in the central portion of the substrate W is minimized by applying a certain current value set to the coils 151, 152, and 153.

As described with reference to FIG. 3, when a density of plasma is controlled only by relying on Lorentz force, the density of the plasma may be controlled only in a direction of moving generated plasma from the central portion to a peripheral portion in the substrate W. Therefore, process distribution may be controlled only in a manner in which the etching rate in the central portion of the substrate W decreases as the magnetic flux density increases by applying a strong magnetic field to the chamber space CH. Comparing the reference distribution map A0 and the lowest distribution map (AMIN), the etching rate in the central portion of the substrate W may be controlled in a range of 0 a.u. to 400 a.u. in a decreasing manner. When the etching rate in the central portion of the substrate W is lower in the reference distribution map A0, it may be difficult to equally control the etching rate of the central and peripheral portions of the substrate W.

According to some implementations, the plasma processing device 100 may locally increase plasma generation efficiency by causing magnetic resonance on a boundary of a sheath region, and process distribution may be controlled in a manner in which an etching rate in a local region increases. The plasma processing device 100 may control current values of the coils 151, 152, and 153 such that magnetic resonance occurs at a position at which the boundary of the sheath region and a central axis of the chamber space CH meet, to control process distribution in a manner such that an etching rate in the central portion of the substrate W increases.

A highest distribution map (AMAX) represents an example distribution map in which an etching rate in the central portion of the substrate W is maximized by applying a certain current value set to the coils 151, 152, and 153. Comparing the reference distribution map A0 and the maximum distribution map (AMAX), the etching rate in the central portion of the substrate W may be controlled in ranges of 0 a.u. to 140 a.u. in an increasing manner.

According to some implementations, the plasma processing device 100 may increase a control range by 35% from 400 a.u. to 540 a.u. using magnetic resonance. In addition, the plasma processing device 100 may control the etching rates of the central and peripheral portions of the substrate W to be equal or substantially equal even when the etching rate in the central portion of the substrate W is lower in the reference distribution map A0.

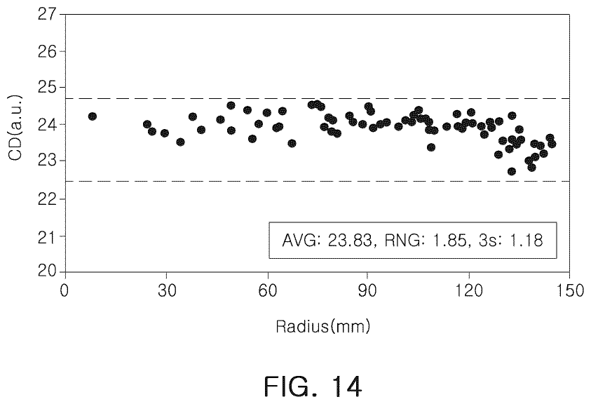

FIG. 14 illustrates a distribution of CD as a function of distance (radius) from a central axis of a substrate W. For example, a position with a radius of ‘0’ represents a center of the substrate W, and a position with a radius of ‘150’ represents an edge of the substrate W. The CD in FIG. 14 is provided by magnetic field control performed by a magnetic field control device in a plasma processing device having the CD, as in FIG. 4.

According to some implementations, a control unit 190, as described with reference to FIGS. 1 and 9, acquires a distribution map indicating process values according to a distance from the center of the substrate W. As illustrated in FIG. 4, when the process value is lower toward the center of the substrate W, the control unit 190 may control current values flowing coils 151, 152, and 153 to generate magnetic resonance at a target position at which a boundary of a sheath region and a central axis of a chamber space meet. Plasma generation efficiency in the central portion of the substrate W may be improved due to the magnetic resonance at the target position, and the CD in the central portion may be adjusted upward as an etching rate in the central portion is adjusted upward.

In some implementations, the control unit 190 may control current value flowing through the coils 151, 152, and 153 to avoid occurrence of the magnetic resonance at the target position, when the process value is lower as a distance from the center of the substrate W increases in the distribution map.

Comparing FIGS. 4 and 14, in FIG. 4, a 3 sigma value for the distribution of CD values may have a difference of 1.65 a.u. from an average value of 23.67 a.u., while in FIG. 14, a 3 sigma value may have a difference of 1.18 from an average value of 23.83 a.u.. For example, the 3 sigma value may be reduced by 28% by adjusting the CD at the center of the substrate W upward as described herein. As a result, the CD for each position of the substrate W may be relatively uniform.

Accordingly, in some implementations, the plasma processing device 100 controls process distribution to be uniform in response to various types of process distribution maps that a chamber space may have.

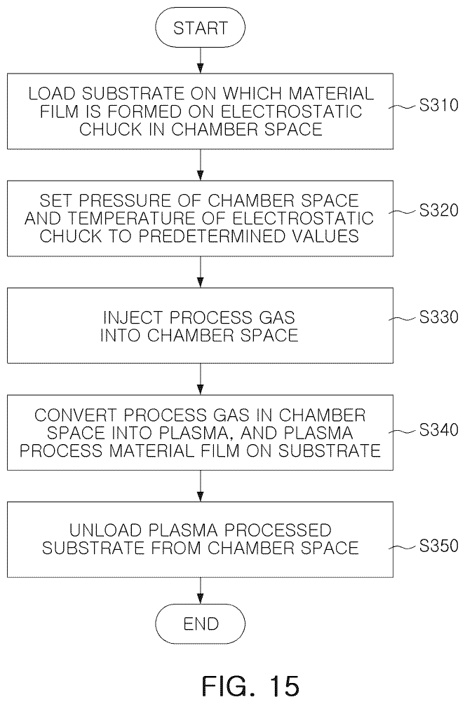

FIG. 15 is a flowchart illustrating a plasma processing method according to some implementations. The plasma processing method using a plasma processing device 100, as described with reference to FIGS. 1 to 14, may include S310 to S350.

In S310, a substrate W on which a material film, for example, an oxide film or a nitride film is formed, is loaded on an electrostatic chuck 140 in a chamber space CH.

In S320, a pressure of the chamber space CH and a temperature of the electrostatic chuck 140 are set to predetermined values. The pressure of the chamber space CH and the temperature of the electrostatic chuck 140 may be process parameters, and may be changed during plasma processing.

In S330, a process gas is injected into the chamber space CH. The process gas may be injected into the chamber space CH using a gas supply device 120, as described with reference to FIG. 1.

In S340, the process gas injected into the chamber space CH is converted into plasma, and the material film on the substrate W is plasma processed. The process gas may be converted into plasma by a first high-frequency power source and/or a second high-frequency power source, applied singly or simultaneously, to an upper electrode 130 and a lower electrode including the electrostatic chuck 140, as described with reference to FIG. 1.

According to some implementations, a magnetic field is formed in the chamber space CH by coils included in a magnetic field control device, and a process value for multiple positions of the substrate W may be controlled by the magnetic field.

For example, according to some implementations, when the process value (e.g., etch rate) is lower toward the central portion of the substrate W, a current value flowing through the coils may be controlled such that the magnetic field is generated at a target position at which a boundary of a sheath region of the chamber space CH and a central axis of the chamber space CH meet. As magnetic resonance occurs at the position, plasma density at the position may increase, and the process value in the central portion of the substrate W may be controlled upward, thereby making the process value for each position of the substrate W uniform.

In addition, or alternatively, OES monitoring of by-products resulting from plasma processing may be performed in real time during plasma processing, and the current value flowing through the coils may be adjusted according to results of the OES monitoring.

The plasma processing may include a process of etching a material film formed on the substrate W, and/or a process of forming a thin film. In some implementations, the plasma processing includes a process of chemically etching the material film formed on the substrate W, and/or a process of physically etching the material film.

In S350, the plasma processing may be completed by unloading plasma processed substrate W from the chamber space CH.

The plasma processing devices described herein may control a magnetic flux density of a magnetic field formed in a chamber space by controlling currents flowing in a plurality of coils at an upper portion of the chamber, and may generate magnetic resonance on a boundary of a sheath region by controlling the magnetic flux density. The magnetic resonance may be generated at a central portion of a substrate to increase plasma density in the central portion of the substrate.

The plasma processing devices described herein may control plasma density distribution not only such that plasma density in a central portion of a substrate decreases but also such that the plasma density in the central portion of the substrate increases, and may thus broadly control process distribution determined by the plasma density. Therefore, the plasma processing device may uniformly control the process distribution in response to various types of process distribution maps that a chamber space may have.

The plasma processing devices described herein may perform optical emission spectroscopy (OES) monitoring, and may correct a current flowing through the plurality of coils in real time to uniformly control process distribution, e.g., to account for differences in process environments of different chambers, process environments changing over time, and the like. Therefore, tool-to-tool matching (TTTM) may be improved, and constancy of process distribution may be improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been illustrated and described above, it will be apparent to those skilled in the art that modifications and variations could be made without departing from the scope of this disclosure.

What is claimed is:

1. A plasma processing device comprising:
a chamber body defining a chamber space;
an electrostatic chuck arranged to support a substrate in the chamber space;
an upper electrode located at an upper portion of the chamber body;
a multiple high-frequency power supply including:
a first power supply configured to apply a first high-frequency power to the upper electrode, and
a second power supply configured to apply a second high-frequency power to the electrostatic chuck,
wherein at least one of the first high-frequency power or the second high-frequency power excites a process gas supplied to the chamber space to form a bulk plasma region and a sheath region in the chamber space, and
wherein the multiple high-frequency power supply is configured to apply the at least one of the first high-frequency power or the second high-frequency power singly or simultaneously;
a magnetic field control device including at least one coil located above the upper electrode, wherein the magnetic field control device is configured to form a magnetic field in the chamber space using at least one current flowing through the at least one coil; and
a control unit configured to control the at least one current flowing through the at least one coil such that a magnetic flux density at a target position on a boundary of the sheath region has a value that results in (i) an electronic rotation period at the target position due to the magnetic field matching (ii) an electronic oscillation period that depends on the at least one of the first high-frequency power and the second high-frequency power.

2. The plasma processing device of claim 1, wherein the target position is located where the boundary of the sheath region and a central axis of the chamber space meet.

3. The plasma processing device of claim 1, wherein the control unit is configured to:
determine the value of the magnetic flux density that results in the electronic rotation period matching the electronic oscillation period;
determine a thickness of the sheath region;
determine at least one value of the at least one current that causes the value of the magnetic flux density to be present at the boundary of the sheath region along a vertical axis passing through a common midpoint of the at least one coil, and
flow the at least one current having the at least one value into the at least one coil.

4. The plasma processing device of claim 3, wherein the control unit is configured to determine the thickness of the sheath region based on at least one of: a temperature of the chamber space, a potential difference between the boundary of the sheath region and the electrostatic chuck, a pressure of the chamber space, and a flow rate of the process gas.

5. The plasma processing device of claim 4, wherein the control unit is configured to adjust a determined value of the thickness of the sheath region based on process results.

6. The plasma processing device of claim 3, wherein the control unit is configured to determine the at least one value based on a distance between the at least one coil and the boundary of the sheath region.

7. The plasma processing device of claim 1, wherein the control unit is configured to:
determine, for each set of at least one candidate current value of multiple sets of at least one candidate current value, a corresponding resonance position having, when the set of at least one candidate current value flows through the at least one coil, the value of the magnetic flux density that results in the electronic oscillation period matching the electronic rotation period;
determine the boundary of the sheath region, wherein determining the boundary of the sheath region comprises determining a thickness of the sheath region;
select, from among the multiple sets of at least one current value, a set for which the boundary of the sheath region matches the resonance position corresponding to the set; and
flow the at least one candidate current value set into the at least one coil.

8. The plasma processing device of claim 1, wherein the at least one coil comprises a plurality of coils having different radii, the plurality of coils having a common midpoint that is aligned with a center position of the substrate, and
wherein the magnetic field control device comprises a plurality of power sources configured to independently control magnitudes and directions of currents flowing through the plurality of coils.

9. The plasma processing device of claim 1, wherein the control unit is configured to determine the electronic oscillation period based on at least one of a first frequency of the first high-frequency power, a second frequency of the second high-frequency power, or a third frequency that is a common multiple of the first frequency and the second frequency.

10. The plasma processing device of claim 1, wherein the upper electrode and the electrostatic chuck face each other.

11. A plasma processing device comprising:
a chamber body defining a chamber space;
an electrostatic chuck arranged to support a substrate in the chamber space;
an upper electrode located at an upper portion of the chamber body;
a multiple high-frequency power supply including:
a first power supply configured to apply a first high-frequency power to the upper electrode, and
a second power supply configured to apply a second high-frequency power to the electrostatic chuck,
wherein at least one of the first high-frequency power or the second high-frequency power excites a process gas supplied to the chamber space to form a bulk plasma region and a sheath region in the chamber space, and
wherein the multiple high-frequency power supply is configured to apply the at least one of the first high-frequency power or the second high-frequency power singly or simultaneously;
an optical interface configured to receive light from the chamber space;
a spectrometer configured to monitor a light intensity at a target wavelength of the light;
a magnetic field control device including at least one coil located above the upper electrode, wherein the magnetic field control device is configured to form a magnetic field in the chamber space using at least one current flowing through the at least one coil; and
a control unit configured to:
set at least one initial value of the at least one current,
cause a plasma process to be performed on the substrate, and
based on a measured value of the light intensity at the target wavelength being different from a reference value, adjust the at least one current such that a difference between the measured value and the reference value decreases.

12. The plasma processing device of claim 11, wherein the control unit is configured to determine the at least one initial value such that a magnetic flux density on a boundary of the sheath region has a value that results in (i) an electronic rotation period at a target position due to the magnetic field matching (ii) an electronic oscillation period that depends on the at least one of the first high-frequency power or the second high-frequency power.

13. The plasma processing device of claim 11, wherein the reference value comprises an intensity value acquired in an experimental process environment or by simulation, based on the at least one initial value.

14. The plasma processing device of claim 11, wherein the reference value is an intensity value at which magnetic resonance occurs on a boundary of the sheath region.

15. The plasma processing device of claim 11, wherein the target wavelength comprises a light wavelength emitted by a by-product generated by the plasma process.

16. The plasma processing device of claim 11, wherein the at least one coil comprises a plurality of coils having different radii, wherein the plurality of coils have a common midpoint aligned with a center position of the substrate, and
wherein the control unit is configured to:
determine the difference,
select a first coil from the plurality of coils, and
repeat an operation of adjusting a current flowing in the first coil until the difference converges to a minimum value or converges to a target value or target range.

17. The plasma processing device of claim 16, wherein the control unit is configured to select at least one of the plurality of coils in order of decreasing coil radius, and repeat the operation for the at least one of the plurality of coils.

18. A plasma processing device comprising:
a chamber body defining a chamber space;
an electrostatic chuck arranged to support a substrate in the chamber space;
an upper electrode located at an upper portion of the chamber body;
a multiple high-frequency power supply including:
a first power supply configured to apply a first high-frequency power to the upper electrode, and
a second power supply configured to apply a second high-frequency power to the electrostatic chuck,
wherein at least one of the first high-frequency power or the second high-frequency power excites a process gas supplied to the chamber space to form a bulk plasma region and a sheath region in the chamber space, and
wherein the multiple high-frequency power supply is configured to apply the at least one of the first high-frequency power or the second high-frequency power singly or simultaneously;
a magnetic field control device including at least one coil located above the upper electrode, wherein the magnetic field control device is configured to form a magnetic field in the chamber space using at least one current flowing through the at least one coil; and
a control unit configured to:
acquire a distribution map indicating a process value as a function of a distance from a center of the substrate, and
based on when the process value decreasing toward the center of the substrate in the distribution map, determining at least one value of the at least one current flowing through the at least one coil such that magnetic resonance occurs at a target position at which a boundary of the sheath region and a central axis of the chamber space meet.

19. The plasma processing device of claim 18, wherein the control unit is configured to control the at least one current flowing through the at least one coil such that a magnetic flux density on the boundary of the sheath region has a value that results in (i) an electronic rotation period at the target position due to the magnetic field matching (ii) an electronic oscillation period that depends on the at least one of the first high-frequency power or the second high-frequency power.

20. The plasma processing device of claim 19, wherein the control unit is configured to, based on the process value increasing toward the center of the substrate, determine the at least one value of the at least one current flowing through the at least one coil to avoid occurrence of the magnetic resonance at the target position.
